(19) United States
(12) Patent Application Publication
(10) Pub. No.: US 2025/0038158 A1
(43) Pub. Date: Jan. 30, 2025

(54) SEMICONDUCTOR PACKAGE

(71) Applicant: Samsung Electronics Co., Ltd., Suwon-si (KR)

(72) Inventors: INGYU BAEK, Suwon-si (KR); SOONHYUNG HONG, Suwon-si (KR)

(21) Appl. No.: 18/612,179

(22) Filed: Mar. 21, 2024

(30) Foreign Application Priority Data
Jul. 27, 2023 (KR) 10-2023-0098231

(51) Int. Cl. H01L 25/16; H01L 23/00; H01L 23/31; H01L 23/498; H01L 23/538; H01L 27/146

(52) U.S. Cl. CPC H01L 25/167; H01L 23/3128; H01L 23/49816; H01L 23/5385; H01L 24/16; H01L 27/14627; H01L 27/14634; H01L 24/32; H01L 24/73; H01L 2224/16225; H01L 2224/32225; H01L 2224/73204

(57) ABSTRACT

The present application is directed to a semiconductor package including a package substrate, a connection substrate disposed on the package substrate, a first semiconductor chip disposed on the connection substrate, a second semiconductor chip disposed on the connection substrate and spaced apart from the first semiconductor chip, a molding layer disposed on the package substrate and at least partially covering the connection substrate, the first semiconductor chip, and the second semiconductor chip, and an optical guide member that extends into the molding layer and is disposed on the second semiconductor chip.

### CROSS-REFERENCE TO RELATED APPLICATION

This U.S. nonprovisional application claims priority under 35 U.S.C § 119 to Korean Patent Application No. 10-2023-0098231 filed on Jul. 27, 2023, in the Korean Intellectual Property Office, the disclosure of which is hereby incorporated by reference in its entirety.

### BACKGROUND

The present inventive concepts relate to a semiconductor package, and more particularly, to a semiconductor package with increased capability of concentrating light.

Portable devices have been increasingly demanded in recent electronic product markets, and as a result, a reduction in size and weight of electronic parts mounted on the portable devices is ceaselessly being required. In order to accomplish the reduction in size and weight of the electronic parts, there is a need for technology which can integrate a number of individual devices into a single package as well as technology to reduce individual sizes of mounting parts.

### SUMMARY

Some embodiments of the present inventive concepts provide a semiconductor package with increased capability of concentrating light.

Some embodiments of the present inventive concepts provide a semiconductor package in which an optical guide member is formed to produce a total reflection to minimize optical loss and to reduce optical noise.

The object of the present inventive concepts is not limited to the embodiments mentioned above, and other objects which have not been mentioned above will be clearly understood to those skilled in the art from the following description.

According to some embodiments of the present inventive concepts, a semiconductor package may include a package substrate; a connection substrate disposed on the package substrate; a first semiconductor chip disposed on the connection substrate; a second semiconductor chip disposed on the connection substrate and spaced apart from the first semiconductor chip; a molding layer disposed on the package substrate and at least partially covering the connection substrate, the first semiconductor chip, and the second semiconductor chip; and an optical guide member that extends into the molding layer and is disposed on the second semiconductor chip.

According to some embodiments of the present inventive concepts, a semiconductor package may include a package substrate; a connection substrate disposed on the package substrate; a first semiconductor chip disposed on the connection substrate; a second semiconductor chip disposed on the connection substrate and spaced apart from the first semiconductor chip; a molding layer disposed on the package substrate and at least partially covering the first semiconductor chip; and an optical guide member that extends into the molding layer and is in contact with a top surface of the second semiconductor chip. A bottom surface of the molding layer may reside on a lower plane relative to a bottom surface of the optical guide member where the package substrate defines a base reference plane.

According to some embodiments of the present inventive concepts, a semiconductor package may include a package substrate; a connection substrate disposed on the package substrate, the connection substrate includes a base substrate, a plurality of upper pads on a top surface of the base substrate, a plurality of lower pads on a bottom surface of the base substrate, and a plurality of through vias that extend into the base substrate and connect the upper pads to the lower pads. The semiconductor package may further include a first semiconductor chip disposed on the connection substrate; a second semiconductor chip disposed on the connection substrate and spaced apart in a first direction from the first semiconductor chip; a molding layer disposed on the package substrate and at least partially covering the first semiconductor chip, the second semiconductor chip, and the connection substrate; a plurality of first connection terminals that connect the upper pads of the connection substrate to the first semiconductor chip and connect the connection substrate to the upper pads of the second semiconductor chip; a plurality of second connection terminals that connect the package substrate to the lower pads of the connection substrate; and an optical guide member that penetrates the molding layer and is disposed on the second semiconductor chip to guide a path of light.

### BRIEF DESCRIPTION OF DRAWINGS

FIG. 1 illustrates a simplified plan view showing a semiconductor package according to some embodiments of the present inventive concepts.

FIG. 2 illustrates a cross-sectional view taken along line A-A′ of the semiconductor package of FIG. 1, showing a semiconductor package according to some embodiments of the present inventive concepts.

FIG. 3A illustrates an enlarged cross-sectional view showing section A of the semiconductor package of FIG. 2.

FIG. 3B illustrates an enlarged cross-sectional view showing a modified example of the semiconductor package of FIG. 3A, according to some embodiments of the present inventive concepts.

FIG. 4 illustrates an enlarged cross-sectional view showing a second semiconductor chip of the semiconductor package of FIG. 2, according to some embodiments of the present inventive concepts.

FIGS. 5 to 7 illustrate cross-sectional views showing a semiconductor package according to some embodiments of the present inventive concepts.

FIGS. 8 to 12 illustrate cross-sectional views showing a method of fabricating a semiconductor package according to some embodiments of the present inventive concepts.

### DETAILED DESCRIPTION OF EMBODIMENTS

The following will now describe some embodiments of the present inventive concepts with reference to the accompanying drawings. Like reference numerals may indicate like components throughout the description.

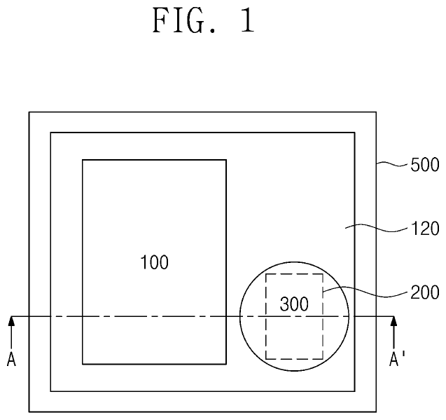

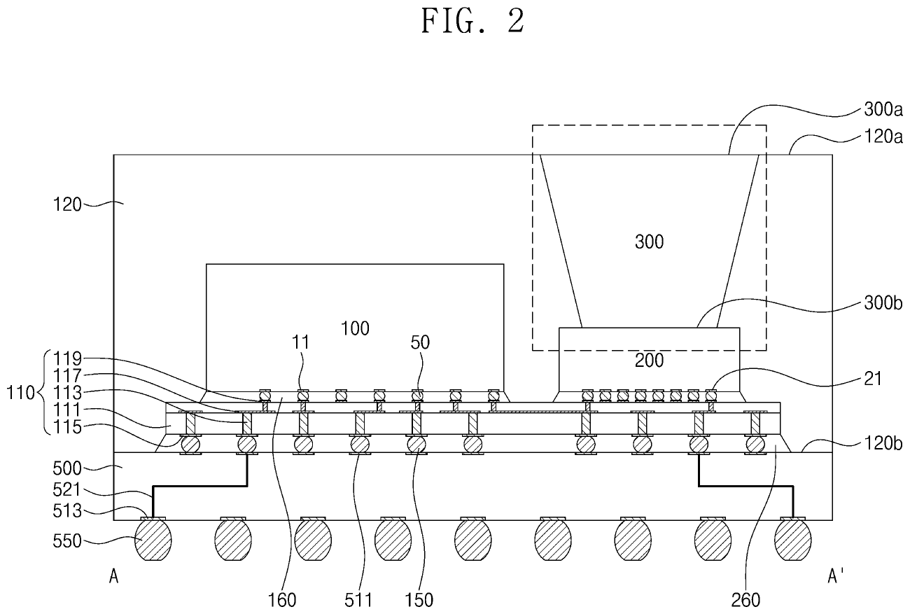

FIG. 1 illustrates a simplified plan view showing a semiconductor package according to some embodiments of the present inventive concepts. FIG. 2 illustrates a cross-sectional view taken along line A-A′ of the semiconductor package of FIG. 1, showing a semiconductor package according to some embodiments of the present inventive concepts.

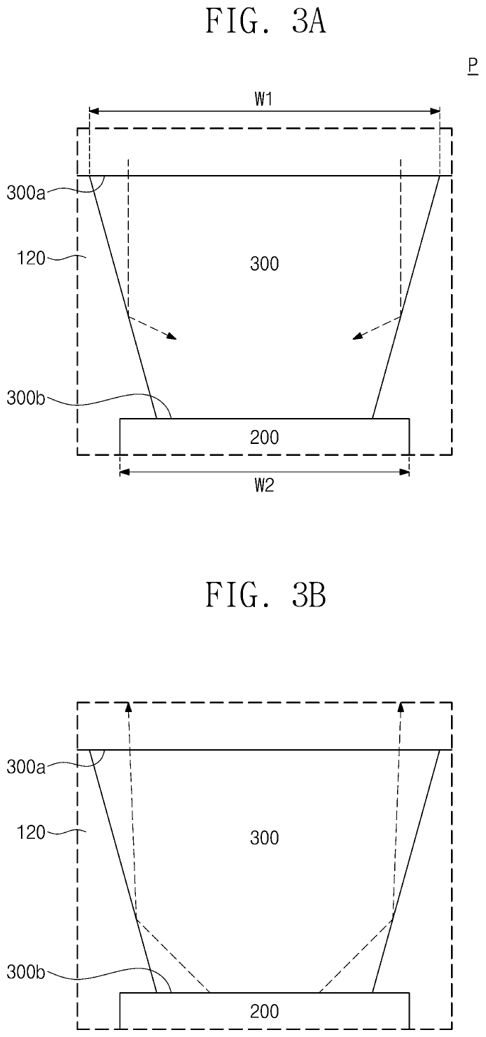

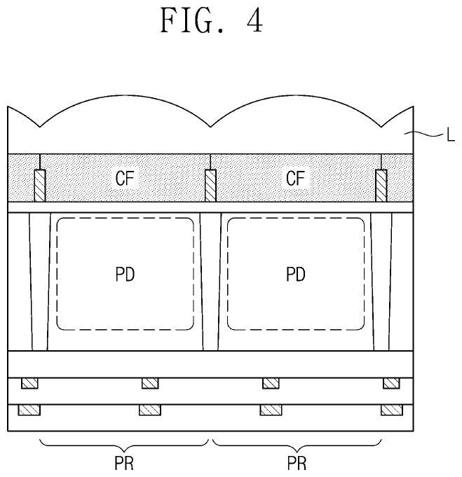

FIG. 3A illustrates an enlarged cross-sectional view showing section A of the semiconductor package of FIG. 2. FIG. 3B illustrates an enlarged cross-sectional view showing a modified example of the semiconductor package of FIG. 3A, according to some embodiments of the present inventive concepts. FIG. 4 illustrates an enlarged cross-sectional view showing a second semiconductor chip of the semiconductor package of FIG. 2, according to some embodiments of the present inventive concepts.

Referring to FIGS. 1 to 4, in some embodiments, a semiconductor package may include first and second semiconductor chips 100 and 200, a connection substrate 110, an optical guide member 300, and a package substrate 500.

As shown in FIG. 2, the first and second semiconductor chips 100 and 200 may be disposed on a top surface of the connection substrate 110. The first and second semiconductor chips 100 and 200 may be connected through one or more first connection terminals 50 to the connection substrate 110.

In some embodiments, as shown in FIG. 2, the first semiconductor chip 100 may have a plurality of chip pads 11 on a bottom surface thereof, and the second semiconductor chip 200 may have a plurality of chip pads 21 on a bottom surface thereof. The first connection terminals 50 may be attached to the chip pads 11 and 21 of the first and second semiconductor chips 100 and 200. The first connection terminals 50 may be one or more of solder balls, conductive bumps, and conductive pillars. The first connection terminals 50 may include at least one metallic material selected from copper, tin, and/or lead.

The first semiconductor chip 100 may be a logic chip including a processor, such as a microelectromechanical system (MEMS) device, an optoelectronic device, a central processing unit (CPU), a graphic processing unit (GPU), a mobile application, or a digital signal processor (DSP).

As shown in FIG. 2, in some embodiments, the second semiconductor chip 200 may be spaced apart from the first semiconductor chip 100 and disposed on the connection substrate 110. The second semiconductor chip 200 may include at least one selected from light emitting devices and passive devices. For example, in some embodiments, when the second semiconductor chip 200 is the light emitting device, light emitted from the second semiconductor chip 200 may pass through the optical guide member 300 and escape from the semiconductor package. Alternatively, in some embodiments, when the second semiconductor chip 200 is the passive device, light incident on the semiconductor package may pass through the optical guide member 300 and concentrate on the second semiconductor chip 200. The light emitting device may include at least one selected from a light emitting diode (LED), an organic light emitting diode (OLED), and a laser diode. The passive device may include at least one selected from an image sensor (e.g., CIS), a charge coupled device (CCD), a fingerprint sensor, a proximity sensor, an optical sensor, a solar cell, and a light detection sensor.

In some embodiments, as shown in FIG. 2, the connection substrate 110 may be disposed on the package substrate 500 and connected through one or more second connection terminals 150 to the package substrate 500. The connection substrate 110 may include a chip region and an edge region that surrounds the chip region. In some embodiments, the first and second semiconductor chips 100 and 200 may be disposed on the chip region of the connection substrate 110.

Still referring to FIG. 2, in some embodiments, the connection substrate 110 may include a base substrate 111, a plurality of through vias 113, a redistribution layer including a plurality of connection lines 117, and a plurality of lower and upper pads 115 and 119.

In some embodiments, the base substrate 111 may be a silicon substrate or a silicon-on-insulator (SOI) substrate. Alternatively, in some embodiments, the base substrate 111 may be a glass substrate, a ceramic substrate, a polymer substrate, or any suitable substrate that can provide proper protection and/or an interconnection function. The base substrate 111 may include active electronic devices and/or passive electronic devices. A passivation dielectric layer may be disposed on each of top and bottom surfaces of the base substrate 111.

The plurality of through vias 113 may penetrate the base substrate 111, and the through vias 113 and the connection lines 117 may include a metallic material, such as tungsten (W), aluminum (Al), or copper (Cu).

The lower pads 115 may be disposed on a bottom surface of the connection substrate 110, and the upper pads 119 may be disposed on a top surface of the connection substrate 110. The lower pads 115 may be electrically connected to the upper pads 119 through the plurality of through vias 113 and the connection lines 117.

The second connection terminals 150 may be attached to the lower pads 115 of the connection substrate 110. The second connection terminals 150 may be electrically connected to the upper pads 119 through the lower pads 115, the through vias 113, and the connection lines 117. The second connection terminals 150 may be solder balls formed of one or more of tin, lead, and copper.

Likewise, the first connection terminals 50 may be attached to the upper pads 119 of the connection substrate 110. The first connection terminals 50 may connect the upper pads 119 to the first semiconductor chip 100 and may connect the upper pads 119 to the second semiconductor chip 200.

In some embodiments, as shown in FIG. 2, a molding layer 120 may be disposed on the package substrate 500. The molding layer 120 may be disposed either on the top surface of the connection substrate 110 or on a top surface of the package substrate 500. For example, as shown in FIG. 2, in some embodiments, when the molding layer 120 is disposed on the top surface of the package substrate 500, a sidewall of the molding layer 120 may be aligned with a sidewall of the package substrate 500. The molding layer 120 may be disposed on the top surface of the package substrate 500, thereby covering a sidewall of the connection substrate 110. Therefore, a bottom surface 120b of the molding layer 120 may be in contact with the top surface of the package substrate 500. In some embodiments, the bottom surface 120b of the molding layer 120 may be located lower relative to a bottom surface 300b of the optical guide member 300 and that of the bottom surface of the connection substrate 110.

In some embodiments, the molding layer 120 may cover the first semiconductor chip 100, and may also cover at least a portion of the connection substrate 110 and at least a portion of the second semiconductor chip 200. A top surface 120a of the molding layer 120 may be coplanar with a top surface 300a of the optical guide member 300. In addition, in some embodiments, the bottom surface 120b of the molding layer 120 may be in contact with the top surface of the connection substrate 110, and may reside on a lower plane relative to the bottom surface 300b of the optical guide member 300. The molding layer 120 may include a dielectric polymer, such as an epoxy molding compound (EMC).

Still referring to FIG. 2, in some embodiments, a first underfill layer 160 may be interposed between the first semiconductor chip 100 and the connection substrate 110 and between the second semiconductor chip 200 and the connection substrate 110. The first underfill layer 160 may be provided and, in some embodiments, fill a space, between the first connection terminals 50. The first underfill layer 160 may include, for example, a thermo-curable or photo-curable resin. The first underfill layer 160 may further include inorganic fillers or organic fillers. A second underfill layer 260 may be provided and, in some embodiments, fill a space, between the connection substrate 110 and the package substrate 500. The second underfill layer 260 may include a same material or similar material to that of the first underfill layer 160.

In some embodiments, as shown in FIG. 2, the optical guide member 300 may be disposed on a top surface of the second semiconductor chip 200 (see also FIGS. 3A-3B), and may be optically transparent. Therefore, light may pass through the optical guide member 300 to reach the second semiconductor chip 200. Moreover, the optical guide member 300 may concentrate light incident on the second semiconductor chip 200 from an upside of the second semiconductor chip 200 or emitted from the second semiconductor chip 200 toward an upside of the second semiconductor chip 200.

Referring to FIGS. 2, 3A, and 4, in some embodiments, light may move through the optical guide member 300 to the second semiconductor chip 200. Light may be incident on the optical guide member 300 through an upper surface of the optical guide member 300. In some embodiments, the optical guide member 300 may have a refractive index greater than that of the molding layer 120, and light in the optical guide member 300 may be totally reflected in the optical guide member 300. Therefore, most of light incident on the optical guide member 300 may move to the second semiconductor chip 200. For example, in some embodiments, about 80% or more of the light incident on the optical guide member 300 may move to the second semiconductor chip 200.

The optical guide member 300 may reduce optical loss by producing a total reflection of incident light, and decrease optical noise by fundamentally suppressing scattered reflection of light caused by other structures.

As shown in FIGS. 3A-3B, the optical guide member 300 may have a diameter that decreases in a direction from the top surface 300a toward the bottom surface 300b (see also FIG. 2). For example, in some embodiments, the optical guide member 300 may have a tapered shape in which diameter decreases as the distance from the second semiconductor chip 200 decreases. A diameter W1 of the top surface 300a of the optical guide member 300 may be greater than a diameter W2 of the top surface of the second semiconductor chip 200. The width W2 of the top surface of the second semiconductor chip 200 may denote a length in a direction parallel to the diameter W1 of the top surface 300a of the optical guide member 300. Thus, the top surface 300a of the optical guide member 300 may receive a large amount of externally incident light, and the incident light may be transmitted to the second semiconductor chip 200. For example, in some embodiments, the top surface 300a of the optical guide member 300 may receive 80% or more of externally incident light which may be transmitted to the second semiconductor chip 200.

According to some embodiments of the present inventive concepts, the semiconductor package may have increased light concentration efficiency.

The optical guide member 300 may include at least one selected from silicon (Si), nitrogen (N), carbon (C), and metal oxide.

According to some embodiments of the present inventive concepts, the optical guide member 300 may include a lens. For example, in some embodiments, at least a portion of the optical guide member 300 may be constituted by the lens. In some embodiments, a path of light may be changed as the light passes through the lens. In some embodiments, the lens may be formed of glass or plastic, but the present inventive concepts are not limited thereto.

The second semiconductor chip 200 may receive light that has passed through the optical guide member 300. The second semiconductor chip 200 may include a passive device, such as an image sensor (e.g., CIS), as discussed above.

Referring now to FIG. 4, in some embodiments, an image sensor (i.e., passive device) of the second semiconductor chip 200 may include a microlens L, a color filter CF, and a photoelectric conversion element PD. The microlens L and the color filter CF may concentrate and filter incident light, and may provide the photoelectric conversion element PD with the light. The photoelectric conversion element PD may be provided on each of a plurality of pixel regions PR. In the photoelectric conversion element PD, a p-n junction may constitute a photodiode, and the photodiode may generate and accumulate photo-charges in proportion to the intensity of incident light. According to embodiments of the present inventive concepts, it may be possible to increase an amount of light incident on the microlens L and the color filter CF.

FIG. 3B is an enlarged view of a modified example of the semiconductor package of FIG. 3A, according to embodiments of the present inventive concepts, showing a semiconductor package having a light emitting device disposed as the second semiconductor chip 200.

As shown in FIG. 3B, in some embodiments, when a light emitting device is disposed as the second semiconductor chip 200, the light emitting device may serve as a light source. Light emitted from the light emitting device may be incident on the optical guide member 300 positioned on the top surface of the second semiconductor chip 200. Likewise, as shown in FIG. 3A, in some embodiments, the optical guide member 300 may have a refractive index greater than that of the molding layer 120, and light incident on the optical guide member 300 may be totally reflected at an interface between the molding layer 120 and the optical guide member 300. In some embodiments, most of an amount of light emitted from the light emitting device may be transmitted to an outside of the semiconductor package. For example, in some embodiments, about 80% or more of the light emitted from the light emitting device may be transmitted to the outside of the semiconductor package.

Referring back to FIGS. 1 to 4, in some embodiments, the package substrate 500 may be, for example, a printed circuit board, a flexible substrate, or a tape substrate. For example, in some embodiments, the package substrate 500 may be one of a flexible printed circuit board, a rigid printed circuit board, and any combination thereof, each of which boards includes internal wiring lines 521 formed therein.

As shown in FIG. 2, the package substrate 500 may have top and bottom surfaces that face each other, and may include a plurality of upper bonding pads 511, a plurality of external bonding pads 513, and internal wiring lines 521 extending therebetween. The upper bonding pads 511 may be arranged on the top surface of the package substrate 500, and the external bonding pads 513 may be arranged on the bottom surface of the package substrate 500. The upper bonding pads 511 may be electrically connected through the internal wiring lines 521 to respective external bonding pads 513. In some embodiments, external bonding terminals 550 may be attached to the external bonding pads 513. A ball grid array (BGA) may be provided as the external bonding terminals 550.

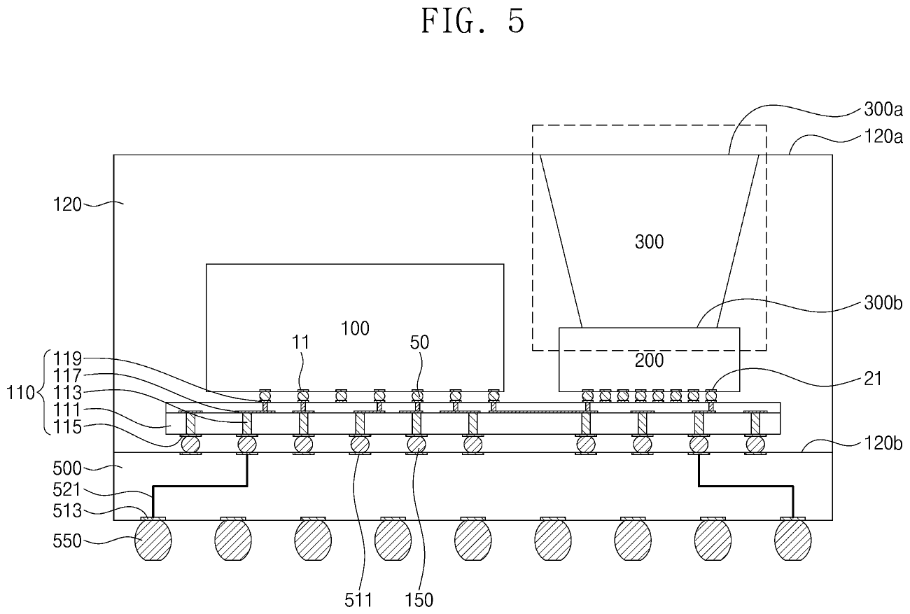

FIGS. 5 to 7 illustrate cross-sectional views showing a semiconductor package according to some embodiments of the present inventive concepts. For brevity of description, the same technical features as those discussed with reference to FIGS. 1 to 4 will be omitted, and a difference thereof will be described in detail below.

Referring to FIG. 5, in some embodiments, the first underfill layer (see, e.g., 160 of FIG. 2) may be omitted between the connection substrate 110 and the first semiconductor chip 100 and between the connection substrate 110 and the second semiconductor chip 200. Instead, in some embodiments, the molding layer 120 may be provided and, in some embodiments, fill a space between the connection substrate 110 and the bottom surfaces of the first and second semiconductor chips 100 and 200. In addition, in some embodiments, the second underfill layer (see, e.g., 260 of FIG. 2) may also be omitted between the connection substrate 110 and the package substrate 500. Likewise, in some embodiments, the molding layer 120 may also be provided and, in some embodiments, fill a space between the connection substrate 110 and the package substrate 500.

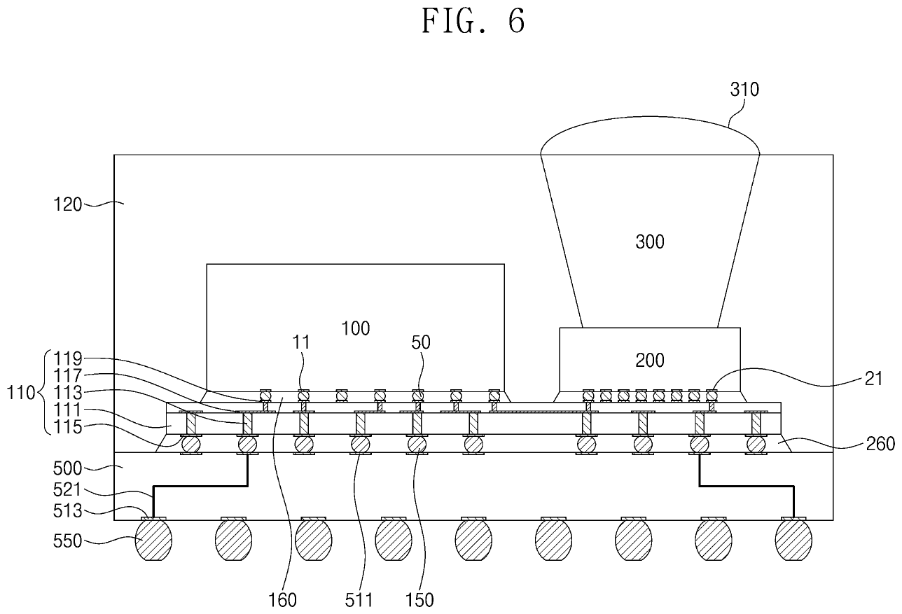

Referring to FIG. 6, in some embodiments, a first lens 310 may be additionally disposed on a top surface of the optical guide member 300. The first lens 310 may be in contact with the top surface of the optical guide member 300, and may refract light externally incident on the optical guide member 300. For example, in some embodiments, light vertically incident on the optical guide member 300 may be refracted and concentrated on the second semiconductor chip 200.

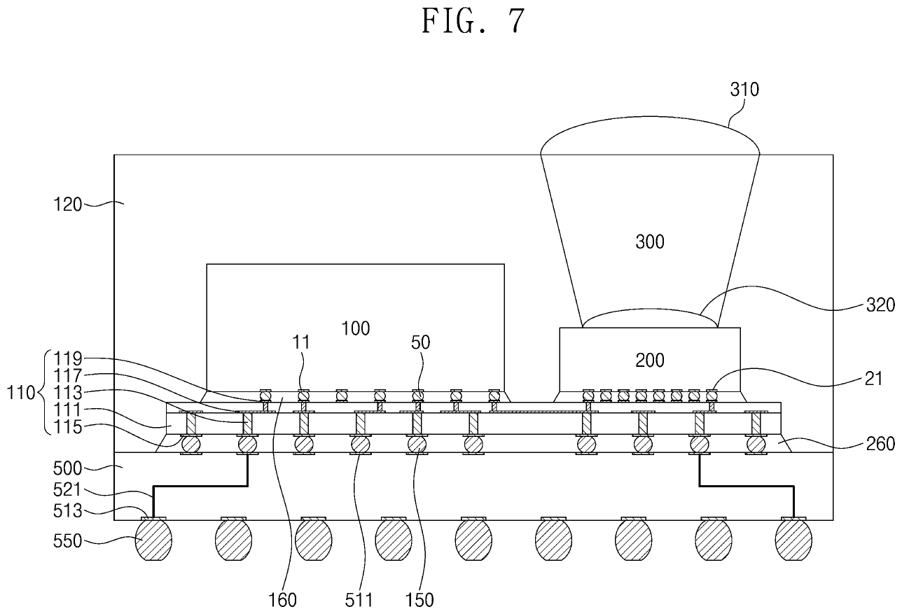

Referring to FIG. 7, in some embodiments, a second lens 320 may be additionally disposed on a bottom surface of the optical guide member 300. The second lens 320 may be in contact with the bottom surface 300b of the optical guide member 300, and may refract light that has passed through the optical guide member 300. The second lens 320 may cause light to be refracted and vertically incident toward the second semiconductor chip 200.

The first and second lenses 310 and 320 may have their refractive indices different from that of the optical guide member 300. For example, in some embodiments, the first lens 310 may have a refractive index less than that of the optical guide member 300, and the second lens 320 may have a refractive index greater than that of the optical guide member 300. Therefore, light may be additionally refracted while passing through the first and second lenses 310 and 320. In this sense, the first and second lenses 310 and 320 may concentrate light, which is incident on the optical guide member 300, on the second semiconductor chip 200. The first and second lenses 310 and 320 may increase an amount of externally incident light, and may induce a reduction in image distortion. For example, in some embodiments, the first and second lenses 310 and 3120 may increase the externally incident light by about 80% or more.

In some embodiments, the first and second lenses 310 and 320 may be fixed through adhesives to the optical guide member 300. The first and second lenses 310 and 320 may be formed of glass or plastic, but the present inventive concepts are not limited thereto.

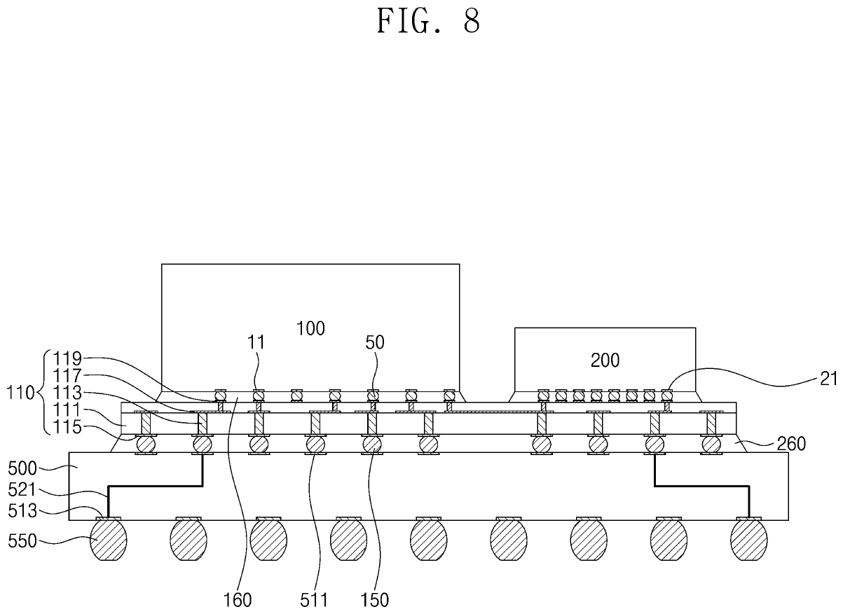

FIGS. 8 to 12 illustrate cross-sectional views showing a method of fabricating a semiconductor package according to some embodiments of the present inventive concepts.

Referring to FIG. 8, in some embodiments, first and second semiconductor chips 100 and 200 may be attached to a connection substrate 110.

For example, in some embodiments, the first semiconductor chip 100 may include a plurality of chip pads 11 on a bottom surface thereof, and the second semiconductor chip 200 may include a plurality of chip pads 21 on a bottom surface thereof. The first and second semiconductor chips 100 and 200 may be disposed on the connection substrate 110 to allow the chip pads 11 and 21 to face a top surface of the connection substrate 110. The chip pads 11 and 21 of the first and second semiconductor chips 100 and 200 may be connected through one or more first connection terminals 50 to a plurality of upper pads 119 of the connection substrate 110. After the attachment of the first and second semiconductor chips 100 and 200, a first underfill layer 160 may fill a space between the first connection terminals 50. In contrast, as shown in FIG. 5, in some embodiments, the formation of the first underfill layer 160 may be omitted.

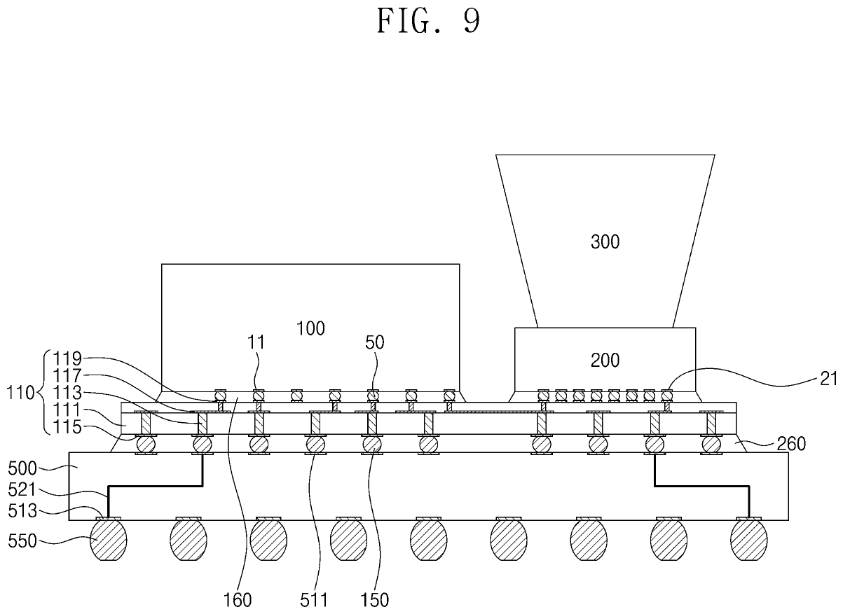

Referring to FIG. 9, in some embodiments, an optical guide member 300 may be disposed on the second semiconductor chip 200. For example, in some embodiments, the optical guide member 300 may include at least one selected from silicon (Si), nitrogen (N), carbon (C), and metal oxide, and may be molded by supplying a mold frame with at least one of selected from silicon (Si), nitrogen (N), carbon (C), and metal oxide, and curing the material supplied to the mold frame. Alternatively, in some embodiments, the optical guide member 300 may be constituted by a single unitary lens. In this case, the lens may be formed of glass or plastic, and may be injection molded into a single object. The optical guide member 300 is not limited to that discussed above, and the optical guide member 300 may be formed by supplying a mold frame with at least one of selected from silicon (Si), nitrogen (N), carbon (C), and metal oxide, curing the material supplied to the mold frame, and partially inserting the lens into the cured material.

The optical guide member 300 may be optically transparent, and may allow most of externally incident light to pass therethrough. For example, in some embodiments, the optical guide member 300 may allow 80% or more of externally incident light to pass therethrough. In addition, the optical guide member 300 may have a tapered structure in which the diameter decreases in a direction from top to bottom surfaces of the optical guide member 300, and may cause a large amount of light to reach the second semiconductor chip 200. For example, in some embodiments, the optical guide member 300 may cause 80% or more of the light to reach the second semiconductor chip 200.

The optical guide member 300 may be disposed on a top surface of the second semiconductor chip 200 and may be in contact with the second semiconductor chip 200. For example, in some embodiments, the optical guide member 300 and the second semiconductor chip 200 may be attached through an adhesive tape, and the adhesive tape may be optically transparent. The optical guide member 300 may be adhered and fixed through the adhesive tape to the second semiconductor chip 200.

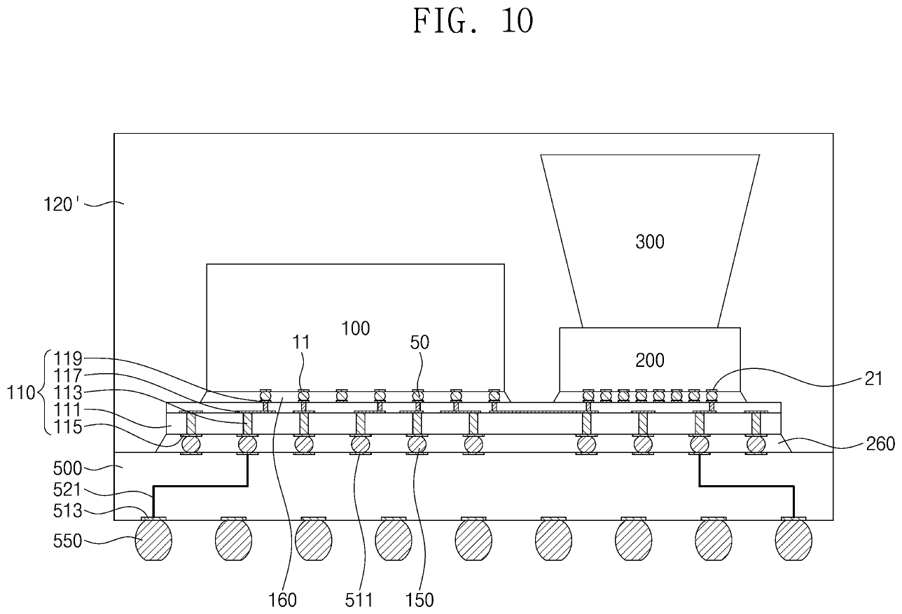

Referring to FIG. 10, in some embodiments, a molding layer 120′ may be formed to cover the first and second semiconductor chips 100 and 200 and the optical guide member 300. The molding layer 120′ may have a top surface residing on a higher plane relative to the optical guide member 300. The molding layer 120′ may fill a space between the first and second semiconductor chips 100 and 200. The molding layer 120′ may include a dielectric polymer, such as an epoxy molding compound (EMC).

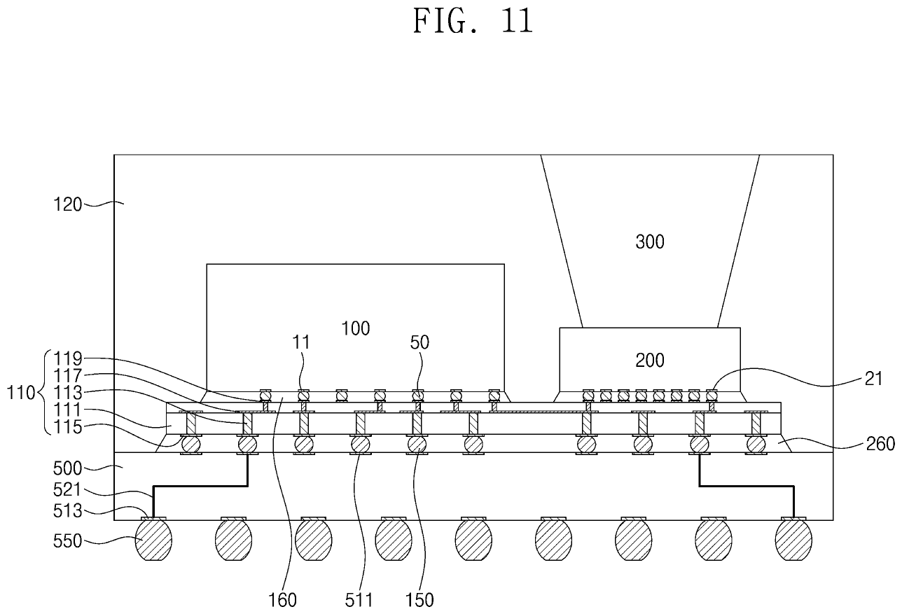

Referring to FIG. 11, in some embodiments, after the formation of the molding layer 120′, a thinning process may be performed on the molding layer (see 120′ of FIG. 10). The thinning process may include a grinding process, a chemical mechanical polishing process, or an etching process. After the thinning process, a thinned molding layer 120 may have a top surface located substantially coplanar with a top surface of the optical guide member 300. In addition, the top surface of the optical guide member 300 may be outwardly exposed of a semiconductor package.

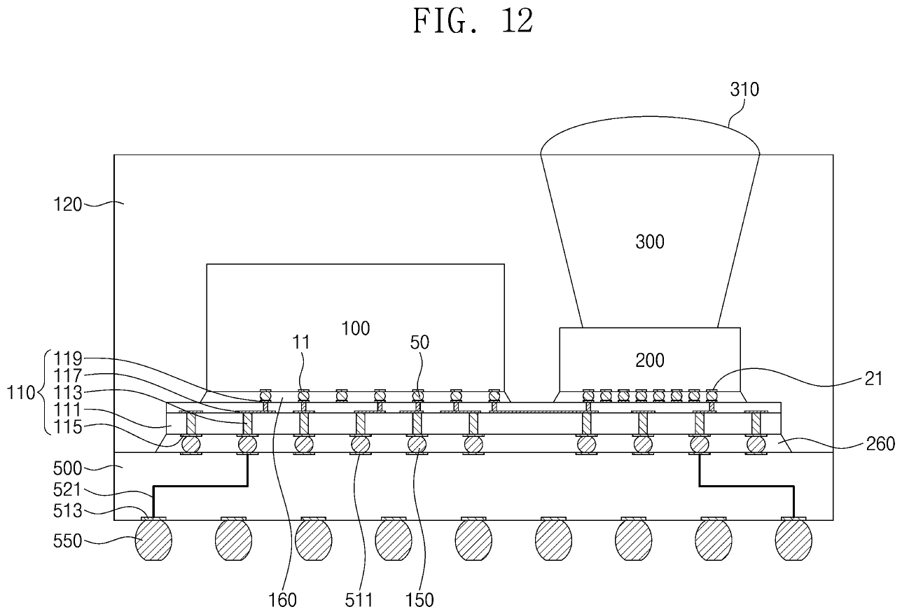

Referring to FIG. 12, in some embodiments, a first lens 310 may be disposed on the optical guide member 300. The first lens 310 may be in contact with the top surface of the optical guide member 300, and may be fixed through an adhesive to the top surface of the optical guide member 300.

According to some embodiments of the present inventive concepts, a semiconductor package may have increased capability of concentrating light.

According to some embodiments of the present inventive concepts, an optical guide member may be formed to produce a total reflection of incident light to thereby minimize optical loss, and to fundamentally suppress scattered reflection of light caused by other structures to thereby reduce optical noise.

In addition, it may be possible to increase an amount of externally incident light and to induce a reduction in image distortion.

As used herein, an element or region that is “covering” or “surrounding” or “filling” another element or region may completely or partially cover or surround or fill the other element or region.

Although terms (e.g., first, second or third) may be used herein to describe various elements, these elements should not be limited by these terms. These terms are only used to distinguish one element from another. For example, a first element may be referred to as a second element, and, similarly a second element may be referred to as a first element without departing from the teachings of the disclosure.

Although the present invention has been described in connection with the embodiments of the present invention illustrated in the accompanying drawings, it will be understood to those skilled in the art that various changes and modifications may be made without departing from the technical spirit and essential feature of the present invention. The above-disclosed subject matter is to be considered illustrative, and not restrictive, and the appended claims are intended to cover all such modifications, enhancements, and other embodiments, which fall within the scope of the present inventive concept. Thus, to the maximum extent allowed by law, the scope is to be determined by the broadest permissible interpretation of the following claims and their equivalents, and shall not be restricted or limited by the foregoing detailed description.

What is claimed is:

1. A semiconductor package, comprising:
a package substrate;
a connection substrate disposed on the package substrate;
a first semiconductor chip disposed on the connection substrate;
a second semiconductor chip disposed on the connection substrate and spaced apart from the first semiconductor chip;
a molding layer disposed on the package substrate and at least partially covering the connection substrate, the first semiconductor chip, and the second semiconductor chip; and
an optical guide member that extends into the molding layer and is disposed on the second semiconductor chip.

2. The semiconductor package of claim 1, wherein a diameter of a top surface of the optical guide member is greater than a width of a top surface of the second semiconductor chip.

3. The semiconductor package of claim 1, wherein a top surface of the optical guide member is coplanar with a top surface of the molding layer.

4. The semiconductor package of claim 1, wherein a bottom surface of the molding layer resides on a lower plane relative to a bottom surface of the optical guide member where the package substrate defines a base reference plane.

5. The semiconductor package of claim 1, wherein a bottom surface of the molding layer resides on a lower plane relative to a bottom surface of the connection substrate where the package substrate defines a base reference plane.

6. The semiconductor package of claim 1, wherein a refractive index of the optical guide member is greater than a refractive index of the molding layer.

7. The semiconductor package of claim 1, wherein the second semiconductor chip includes a microlens, a color filter, and a photoelectric conversion element.

8. The semiconductor package of claim 1, wherein the optical guide member includes a lens.

9. The semiconductor package of claim 1, wherein the optical guide member includes silicon (Si), nitrogen (N), carbon (C), or metal oxide.

10. The semiconductor package of claim 1, further comprising a first lens in contact with a top surface of the optical guide member.

11. The semiconductor package of claim 10, further comprising a second lens between the optical guide member and the connection substrate and in contact with a top surface of the second semiconductor chip.

12. The semiconductor package of claim 1, wherein a bottom surface of the optical guide member is in contact with a top surface of the second semiconductor chip.

13. The semiconductor package of claim 1, wherein the second semiconductor chip includes a passive device or a light emitting device.

14. A semiconductor package, comprising:
a package substrate;
a connection substrate disposed on the package substrate;
a first semiconductor chip disposed on the connection substrate;
a second semiconductor chip disposed on the connection substrate and spaced apart from the first semiconductor chip;
a molding layer disposed on the package substrate and covering the first semiconductor chip; and
an optical guide member that extends into the molding layer and is in contact with a top surface of the second semiconductor chip,
wherein a bottom surface of the molding layer resides on a lower plane relative to a bottom surface of the optical guide member where the package substrate defines a base reference plane.

15. The semiconductor package of claim 14, wherein a diameter of a top surface of the optical guide member is greater than a width of the top surface of the second semiconductor chip.

16. The semiconductor package of claim 14, wherein a top surface of the optical guide member and a top surface of the molding layer are coplanar with each other.

17. The semiconductor package of claim 14, wherein the second semiconductor chip includes a passive device or a light emitting device.

18. The semiconductor package of claim 14, further comprising a first lens in contact with a top surface of the optical guide member.

19. The semiconductor package of claim 18, further comprising a second lens between the optical guide member and the connection substrate and in contact with the top surface of the second semiconductor chip.

20. A semiconductor package, comprising:
a package substrate;
a connection substrate disposed on the package substrate, the connection substrate including a base substrate, a plurality of upper pads on a top surface of the base substrate, a plurality of lower pads on a bottom surface of the base substrate, and a plurality of through vias that extend into the base substrate and connect the upper pads to the lower pads;
a first semiconductor chip disposed on the connection substrate;
a second semiconductor chip disposed on the connection substrate and spaced apart in a first direction from the first semiconductor chip;
a molding layer disposed on the package substrate and at least partially covering the first semiconductor chip, the second semiconductor chip, and the connection substrate;
a plurality of first connection terminals that connect the upper pads of the connection substrate to the first semiconductor chip and connect the connection substrate to the upper pads of the second semiconductor chip;
a plurality of second connection terminals that connect the package substrate to the lower pads of the connection substrate; and
an optical guide member that penetrates the molding layer and is disposed on the second semiconductor chip to guide a path of light.
